(19) United States
(12) Patent Application Publication
(10) Pub. No.: US 2015/0365060 A1
(43) Pub. Date: Dec. 17, 2015

(54) TRANSIMPEDANCE AMPLIFIER AND LIGHT RECEPTION CIRCUIT

(71) Applicant: KABUSHIKI KAISHA TOSHIBA, Tokyo (JP)

(72) Inventor: Yukio TSUNETSUGU, Buzen Fukuoka (JP)

(21) Appl. No.: 14/634,297

(22) Filed: Feb. 27, 2015

(30) Foreign Application Priority Data
Jun. 11, 2014 (JP) 2014-120808

(51) Int. Cl. H03F 17/00; H03F 3/45

(52) U.S. Cl. CPC H03F 17/00; H03F 3/45071; H03F 2203/45336; H03F 2203/45154

(57) ABSTRACT

A transimpedance amplifier includes a first current source, a second current source, an output amplifier, and a bias circuit. The first current source includes a first cascode circuit with two transistors. The second current source includes a second cascode circuit with two transistors. The output amplifier includes a first input terminal to which an output of the first cascode circuit is input and a first output terminal at which an output voltage corresponding to a photocurrent is output. The bias circuit is connected between the first and second current sources. The photocurrent at a phototerminal corresponds to a first current from the first current source subtracted from a sum of a second current from the second current source and a first feedback current from the output amplifier.

### CROSS-REFERENCE TO RELATED APPLICATION

This application is based upon and claims the benefit of priority from Japanese Patent Application No. 2014-120808, filed Jun. 11, 2014, the entire contents of which are incorporated herein by reference.

### FIELD

Embodiments described herein relate generally to a transimpedance amplifier and a light reception circuit.

### BACKGROUND

Light reception circuits including photodiodes and transimpedance amplifiers may be used in converting light signals to electrical signals.

A transimpedance amplifier maybe configured to include an inverting amplifier and a feedback resistor, which feeds back an output signal from the inverting amplifier to the input terminal of the inverting amplifier.

In this configuration, a delay time corresponds to the product of the junction capacitance of a light-receiving element and the feedback resistor value; thus when the feedback resistor value is increased to obtain a predetermined output voltage, the delay time increases and a high-speed response to changes in light signals is therefore difficult to achieve.

### DESCRIPTION OF THE DRAWINGS

FIG. 1 is a circuit diagram of a transimpedance amplifier and a light reception circuit that uses the transimpedance amplifier according to a first exemplary embodiment.

FIG. 2 is a schematic cross-sectional diagram illustrating a photodiode.

FIG. 3 is a circuit diagram illustrating operation of a photocurrent clamp circuit of the transimpedance amplifier according to the first exemplary embodiment.

FIG. 4 is a circuit diagram of a transimpedance amplifier according to a second exemplary embodiment.

FIG. 5A and FIG. 5B are portions of a circuit diagram of a transimpedance amplifier according to a third exemplary embodiment.

FIGS. 6A to 6D are waveform diagrams corresponding to operations of the transimpedance amplifier according to the third exemplary embodiment.

FIG. 7A and FIG. 7B are portions of a circuit diagram of a transimpedance amplifier according to a fourth exemplary embodiment.

FIGS. 8A to 8G are waveform diagrams of the transimpedance amplifier according to operations of the fourth exemplary embodiment.

### DETAILED DESCRIPTION

A transimpedance amplifier and a light reception circuit that may operate with high speed are described.

In general, according to one embodiment, there is provided a transimpedance amplifier that includes a photocurrent terminal, a first current source, a second current source, an output amplifier, and a bias circuit, such as a local negative feedback bias circuit, for example. A photocurrent is supplied at the photocurrent terminal. The first current source includes a first cascode circuit with at least two transistors, and is connected to a ground terminal. The second current source includes a second cascode circuit with at least two transistors. A power supply voltage is supplied to the second current source. The output amplifier includes a first input terminal at which an output of the first cascode circuit is input and a first output terminal that outputs an output voltage corresponding to the photocurrent. A first feedback resistor is connected between the first input terminal and the first output terminal of the output amplifier. The bias circuit is connected between the first current source and the second current source and, is capable of controlling the photocurrent by negatively feeding back a voltage of the photocurrent terminal. The first current source is connected between the bias circuit and a ground terminal. The second current source is connected between a power supply terminal and the bias circuit. The input terminal of the output amplifier is connected to a first feedback node between the bias circuit and the first current source. The photocurrent supplied at a photocurrent terminal corresponds to a first current from the first current source subtracted from a sum of a second current from the second current source and a first feedback current from the first input terminal of the output amplifier.

Hereinafter, exemplary embodiments will be described with reference to the accompanying drawings.

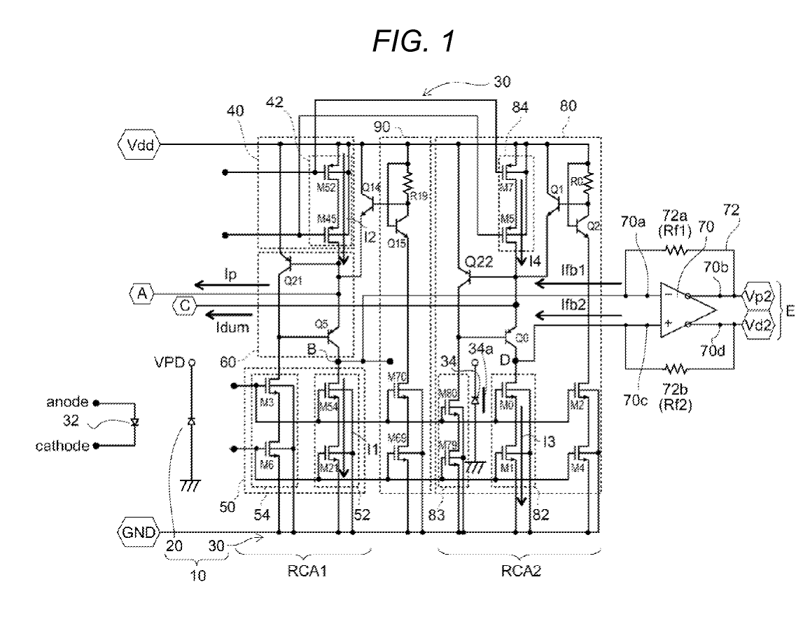

FIG. 1 is a circuit diagram illustrating a transimpedance amplifier and a light reception circuit that uses the transimpedance amplifier according to a first exemplary embodiment.

A transimpedance amplifier 30 includes a photocurrent terminal A, a first current source 50, a second current source 40, an output amplifier 70, a feedback resistor 72, and a local negative feedback bias circuit (bias circuit) 60.

A photodiode 20 is connected to a side of the photocurrent terminal A of the transimpedance amplifier 30. A load (not illustrated) is connected to an output terminal E of the transimpedance amplifier 30. A single output may be made by connecting a comparator circuit between the output terminal E and the load. Collectively, photodiode 20 and transimpedance amplifier 30 may be referred to as light reception device 10.

A photocurrent Ip flows in the photodiode through the photocurrent terminal A when the photodiode 20 is irradiated with light from a light-emitting element 32. When the cathode of the photodiode 20 is connected to the photocurrent terminal A, electrons flow toward the cathode. That is, the photocurrent Ip flows toward the anode from the cathode of the photodiode 20.

The first current source 50 includes a first cascode circuit 52 that is formed by two transistors (M54 & M21). One terminal of the first current source 50 is grounded. The second current source 40 includes a second cascode circuit 42 that is formed by two transistors (M52 & M45). A power supply voltage Vdd is supplied to the second current source 40.

The output amplifier 70 includes a first input terminal 70a to which the other terminal of the first cascode circuit 52 is connected and a first output terminal 70b that outputs an output voltage Vp2 corresponding to the photocurrent Ip.

A first feedback resistor 72a (having a resistor value Rf1) is connected between the first input terminal 70a and the first output terminal 70b.

A second current I2 from the second current source 40 is supplied to the local negative feedback bias circuit 60. A feedback current Ifb1 from the first input terminal 70a of the output amplifier 70 is fed back to the local negative feedback bias circuit 60. The photocurrent Ip results from subtracting a first current I1 of the first current source 50 from the sum of the second current I2 and the feedback current Ifb1. In the present drawing (FIG. 1), a feedback terminal B is a point where the first cascode circuit 52 and the local negative feedback bias circuit 60 are connected to each other.

The output amplifier 70 may be a fully differential amplifier with a second input terminal 70c and a second output terminal 70d. In this case, the output amplifier 70 further includes a second feedback resistor 72b (having resistor value Rf2) that is connected between the second input terminal 70c and the second output terminal 70d.

The transimpedance amplifier 30 may also include a reference current bias circuit 80. The reference current bias circuit 80 includes, for example, a third cascode circuit 82 as a third current source (e.g., M0 & M1), a fourth cascode circuit 84 (e.g., M7 & M5) as a fourth current source, a fifth cascode circuit 83 (e.g., M80 & M79) as a fifth current source, a transistor Q22, and a transistor Q0 of which the emitter is connected to a reference current terminal C. The power supply voltage Vdd is supplied to the fourth cascode circuit 84.

A fourth current I4 from the fourth cascode circuit 84 is supplied to the reference current bias circuit 80. A feedback current Ifb2 from the second output terminal 70d of the output amplifier 70 is fed back to the reference current bias circuit 80. A third current I3 from the third current source is also supplied to the reference current bias circuit 80. A feedback terminal D is a point where, for example, the collector of the transistor Q0 and the second input terminal 70c are connected to each other. A reference current Idum results from subtracting the third current I3 from the sum of the feedback current Ifb2 and the fourth current I4 and flows in a dummy photodiode 34 (the reference current Idum is minute because a light shield plate 34a shields the dummy photodiode 34 from light). The second output terminal 70d outputs an output voltage Vd2 corresponding to the reference current Idum. Therefore, the accuracy of differential output of the output amplifier 70 may be improved, and the output voltage (Vp2−Vd2) may be output from the output terminal E.

As illustrated in the present drawing (FIG. 1), the first cascode circuit 52 may include N-channel MOS transistors, and the second cascode circuit 42 may include P-channel MOS transistors. The local negative feedback bias circuit 60 may include PNP bipolar transistors Q5 and Q21. In this case, the base of the PNP bipolar transistor Q5 is connected to the collector of the PNP bipolar transistor Q21. In addition, the base of the PNP bipolar transistor Q21 is connected to the emitter of the PNP bipolar transistor Q5, thereby forming the photocurrent terminal A. Furthermore, the feedback terminal B is a point where the collector of the PNP bipolar transistor Q5 is connected to the first cascode circuit 52. However, the first cascode circuit 52 may include PNP bipolar transistors, and the second cascode circuit 42 may include PNP bipolar transistors.

The first current source 50 may also include an input unit 54 including N-channel MOS transistors M3 and M6. The reference current bias circuit 80 may also include a resistor RO connected in series with bipolar transistor Q2. Bipolar transistor Q1 is connected between power supply voltage Vdd and a control electrode of transistor Q22. Transistors M17 and M18 may also be included in a bias circuit.

The third cascode circuit 82 may include N-channel MOS transistors, and the fourth cascode circuit 84 may include P-channel MOS transistors. The local negative feedback bias circuit 60 may include PNP bipolar transistors.

Transistors M6, M21, M69, M79, M1, and M4 are MOS transistors in various cascode circuits and operate in the saturation region. Transistors M3, M54, M70, M80, M0, and M2 may operate in the non-saturation region. Transistors M52 and M7 are also MOS transistors in cascode circuits operating in the saturation region. M45 and M5 may also be operating in the saturation region.

The transimpedance amplifier 30 of the present exemplary embodiment illustrated in FIG. 1 is configured to include a first regulated cascode circuit (RCA1), a photocurrent clamp circuit 90, a second regulated cascode circuit (RCA2), the output amplifier 70, and the feedback resistor 72. The first regulated cascode circuit (RCA1) includes the first current source 50, the second current source 40, and the local negative feedback bias circuit 60.

The second regulated cascode circuit (RCA2) includes the third cascode circuit 82, the fourth cascode circuit 84, the fifth cascode circuit 83, the transistor Q0, and the transistor Q22 and generates the reference current Idum with respect to the differential output amplifier 70.

The minimum operating voltage Vmin of the transimpedance amplifier 30 may be expressed as the following Expression 1:

Vmin=2Vbe+2Vds_sat (Expression 1)

where Vds_sat is the drain-to-source saturation voltage and Vbe is the base-to-emitter voltage of transistor Q21.

In the first exemplary embodiment, given that, for example, the Vbe is 0.7 V and the Vds_sat is 0.3 V, the Vmin may be decreased to 2.0 V. Therefore, the transimpedance amplifier 30 may operate with a low power supply voltage. A junction capacitance Cj may also be decreased by increasing a reverse voltage supplied to the photodiode 20 with respect to the supplied power supply voltage Vdd.

Furthermore, the current feedback terminal B may be separated from the photodiode 20. The photodiode 20 may be biased by the first regulated cascode circuit (RCA1) that has a negative feedback. For this reason, a large delay time that is dependent on the time constant and is the product of the feedback resistor value and the junction capacitance Cj does not occur. This facilitates high-speed response of the transimpedance amplifier.

For example, in the present drawing (FIG. 1), the base voltage of the PNP bipolar transistor Q21 decreases, and the base voltage of the PNP bipolar transistor Q5 increases when the photocurrent Ip is generated in the photodiode 20. Consequently, a high-speed negative feedback is applied to increase the base voltage of the PNP bipolar transistor Q21, that is, the voltage of the photodiode 20. As described in the present exemplary embodiment, the local negative feedback for which the voltage gain is low enables more a higher speed response than a high-gain feedback loop. The gain may be increased by providing the output amplifier 70.

When the first current source 50 is formed by a cascade mirror, the first current I1 of the first current source 50 may substantially be the same as the second current I2 of the second current source 40. For this reason, the photocurrent Ip will be the same as the feedback current Ifb1. At this time, a voltage VPD of the photodiode 20 is expressed as the following Expression 2.

VPD=Rf1×Ifb1=Rf1×Ip (Expression 2)

A gain Gtrans of the transimpedance amplifier is expressed as the following Expression 3 when the voltage gain of the output amplifier 70 is sufficiently large.

Gtrans=VPD/Ip=Rf1 (Expression 3)

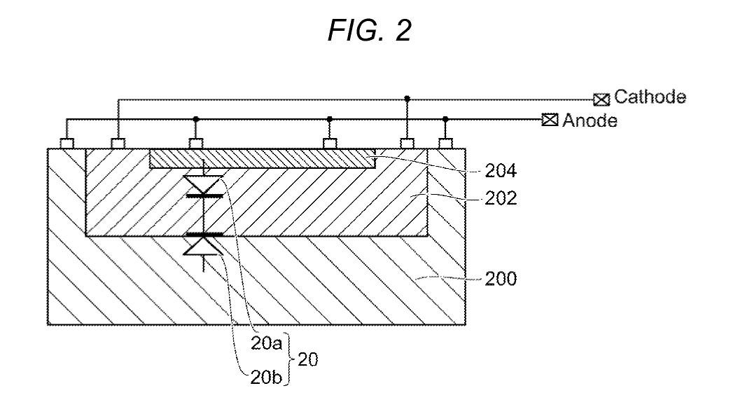

FIG. 2 is a schematic cross-sectional diagram illustrating an example photodiode.

An n-type epitaxial layer 202 is formed in a p-type substrate 200, and a p⁺ diffusion layer 204 is provided in the n-type epitaxial layer 202. In doing so, a first photodiode 20a is formed between the p⁺ diffusion layer 204 and the n-type epitaxial layer 202, and a second photodiode 20b is formed between the p-type substrate 200 and the n-type epitaxial layer 202. Therefore, the conversion efficiency (η) of the photocurrent Ip (η=Ip/IF) may be doubled, where IF is the forward current. However, the junction capacitance Cj is also doubled. In the first exemplary embodiment, the charge and discharge of the junction capacitance Cj is performed using the first regulated cascode circuit (RCA1), not by using the feedback resistor. Therefore, high-speed response may be achieved.

Meanwhile, in a transimpedance amplifier that includes a CMOS-RCA circuit and a resistor bias circuit (for high speed), current consumption is high because of the resistor bias circuit, and dependency on the power supply voltage is high.

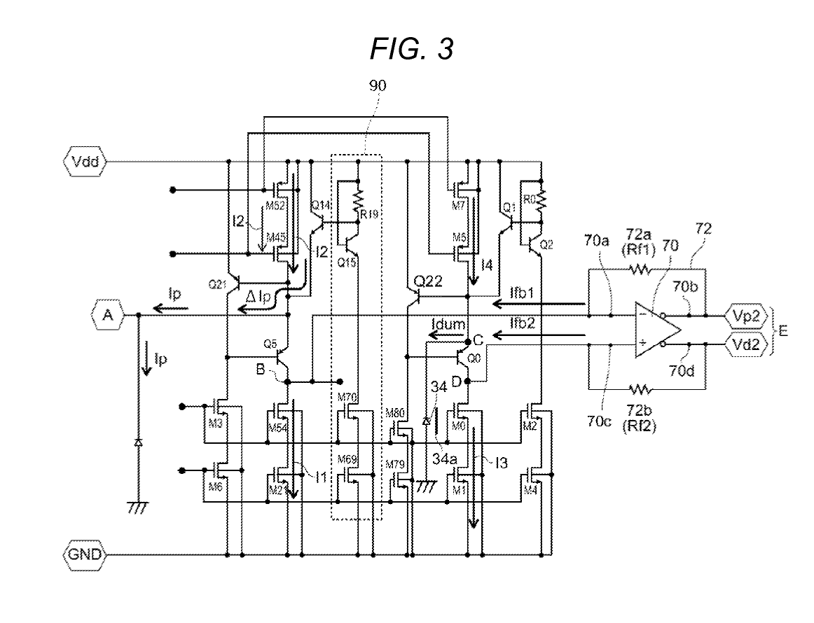

FIG. 3 is a circuit diagram illustrating operation of the photocurrent clamp circuit of the transimpedance amplifier according to the first exemplary embodiment.

The transimpedance amplifier 30 includes the photocurrent clamp circuit 90 provided between a power supply terminal Vdd and a ground GND.

With an alternating current, Vdd=0, and Vbe (base-to-emitter voltage of Q21) is greater than 2×Vds_sat. When the voltage VPD of the photodiode 20 becomes less than or equal to r*i (where i is the emitter current of an NPN transistor Q15, and r is the total resistance of R19 and channel resistance of Q15), a current starts to flow from an NPN transistor Q14. Meanwhile, when the photocurrent Ip is zero, a leakage current flows in the NPN transistor Q14.

With a direct current, the following Expressions 4 and 5 are established.

VPD=Vdd−Vbe (base-to-emitter voltage of Q21) (Expression 4)

Vbe_base (base-to-emitter voltage of Q14)=Vbe (base-to-emitter voltage of Q21)−R19*Ic (collector current of Q15) (Expression 5)

When the photocurrent Ip increases, the photodiode voltage VPD decreases, and when VPD<Vdd−(Vbe−R19*i), a current ΔIp flows toward the photodiode 20 from the NPN transistor Q14. In the above expressions, “R19” is the resistance value of resistor R19 (see e.g., FIG. 1). Under the condition that the photocurrent Ip is relatively large, it is possible that the emitter current of the PNP bipolar transistor Q21 equals the base current of the bipolar PNP transistor Q21. That is, when I1<<Ip, an NPN emitter follower circuit suppresses the voltage drop in the photocurrent terminal A, and the transimpedance amplifier 30 is hard to saturate. In addition, the reference current Idum is a leakage current of the dummy photodiode 34.

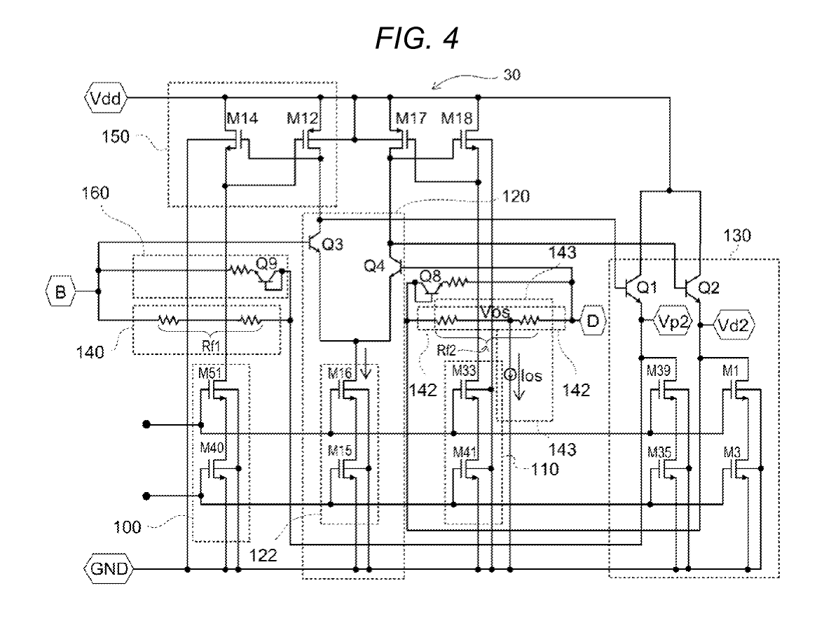

FIG. 4 is a circuit diagram of a transimpedance amplifier according to a second exemplary embodiment. A transimpedance amplifier 30 includes a feedback terminal B, a first current source, a second current source, a differential amplifier 120, a differential buffer amplifier 130, a first feedback resistor 140, a feedback terminal D, a second feedback resistor 142, and a local negative feedback bias circuit 150.

A photocurrent Ip passes through a photocurrent terminal. The first current source is grounded and includes a first cascode circuit 100 that is formed by two transistors (M40 & M51). The second current source is grounded and includes a second cascode circuit 110 that is formed by two transistors (M33 & M41).

The differential amplifier 120 includes a first transistor Q3 of which a first control electrode such as the base thereof is connected to the feedback terminal B, a second transistor Q4 of which a second control electrode such as the base thereof is connected to the feedback terminal D, and a third current source 122 that supplies a tail current. The differential buffer amplifier 130 is connected to the differential amplifier 120 in a cascade manner. The first output voltage Vp2 between the differential buffer amplifier 130 and the feedback terminal B is output in the first feedback resistor 140. The second output voltage Vd2 between the differential buffer amplifier 130 and the feedback terminal D is output in the second feedback resistor 142. A diode connected transistor Q9 may be connected in parallel with the first feedback resistor 140. The third current source 122 may include a cascode circuit including two transistors M16 and M15. The differential buffer amplifier 130 may include transistors M39 and M35 connected between output voltage Vp2 and ground potential GND.

The local negative feedback bias circuit 150 is connected to the first cascode circuit 100, and a power supply voltage Vdd is supplied thereto. The local negative feedback bias circuit 150 applies a negative feedback to the first transistor Q3 in response to the voltage from the feedback terminal B.

Operation of the local negative feedback bias circuit 150 according to the second exemplary embodiment will be described. When a photodiode is irradiated with light, a voltage VPD of the photodiode decreases. The gate and the source voltages of an N-channel MOS transistor M14 increase. Furthermore, the drain voltage of a P-channel MOS transistor M12 decreases. Accordingly, a junction capacitance Cj of the photodiode is charged and discharged with high speed by a regulated cascode circuit including a negative feedback loop.

The transimpedance amplifier 30 may further include a photocurrent clamp circuit 160 that is connected to the first feedback resistor 140 in a parallel manner. This suppresses a voltage drop in the feedback terminal B, and the transimpedance amplifier 30 is hard to be saturated.

The transimpedance amplifier 30 may include an offset circuit 143. The offset circuit 143 draws a current Ios from part of a second feedback resistor Rf2, the second feedback resistor, generates an offset voltage Vos=ΔRf2×Ios, and determines a logic for a no-signal state. Alternatively, the offset voltage Vos may increase the collector current of the transistor Q4 to the current Ios.

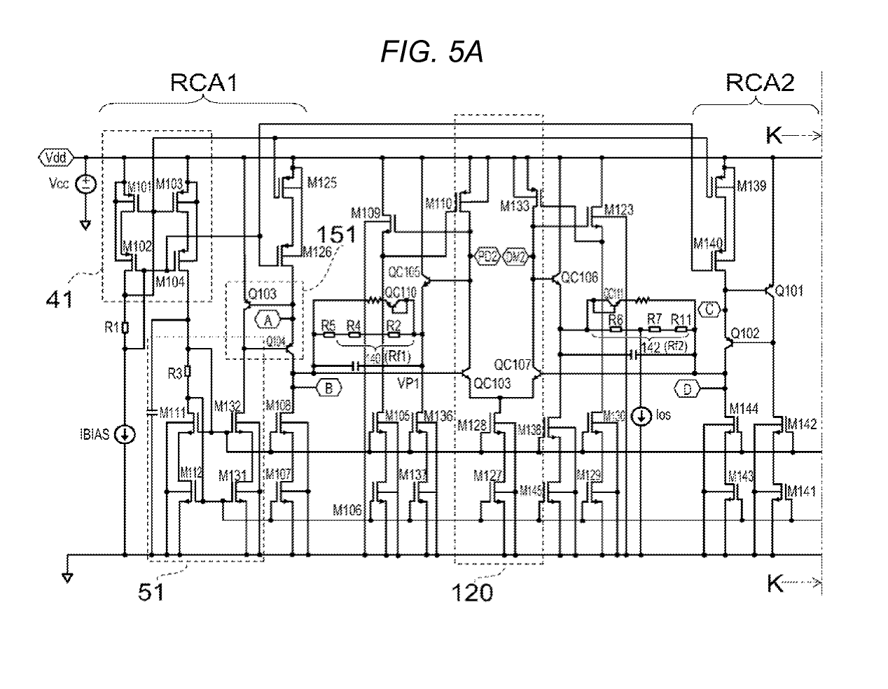

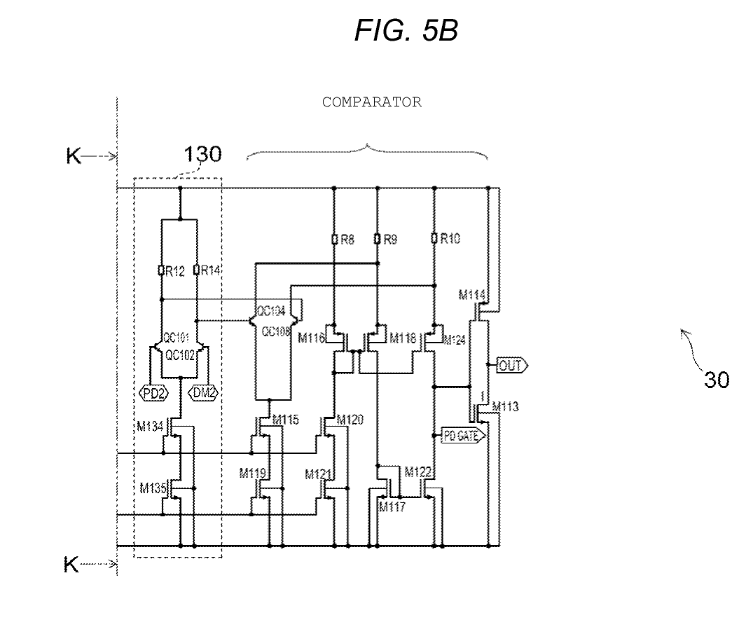

FIG. 5A and FIG. 5B are portions of a circuit diagram of a transimpedance amplifier according to a third exemplary embodiment.

The circuit diagram is divided along line K-K for purposes of display with FIG. 5A depicting elements in the circuit diagram to the left of line K-K and FIG. 5B depicting elements in the circuit diagram to the right of line K-K. A transimpedance amplifier 30 includes a photocurrent terminal A, a first current source 51, a second current source 41, a differential amplifier 120, a differential buffer amplifier 130, a first feedback resistor 140, a second feedback resistor 142, a local negative feedback bias circuit (bias circuit) 151, a feedback terminal B, a reference current terminal C, and a feedback terminal D. An ATC (Auto-Threshold-Control) circuit may be provided in the post-stage of the differential buffer amplifier 130. The first (140) and second (142) feedback resistors may comprise a plurality of resistors connected in series. For example, first feedback resistor 140 may include resistors R5, R4, and R2 and second feedback resistor 142 may include resistors R6, R7, and R11. Additional transistor and resistor elements maybe incorporated into the transimpedance amplifier as depicted in FIG. 5A and FIG. 5B. For example, transistors M109, M139, M133 and resistors R8, R9, R10, R12, and R14 may be included as depicted.

The first current source 51 includes a cascode circuit formed by N-channel MOS transistors M111 and M112. The second current source 41 includes a cascode circuit formed by P-channel MOS transistors M101 and M102 and a cascode circuit formed by P-channel MOS transistors M103 and M104. Thereby, the minimum operating voltage may be decreased. The emitter of QC110 is connected to RCA1 through a resistor. The QC110 acts as a bias circuit when a photocurrent Ip is excessively input to the QC110, and the voltage between both terminals of the first feedback resistor 140 exceeds the base-to-emitter forward voltage Vbe of the QC110. Therefore, the saturation of the transimpedance amplifier may be suppressed.

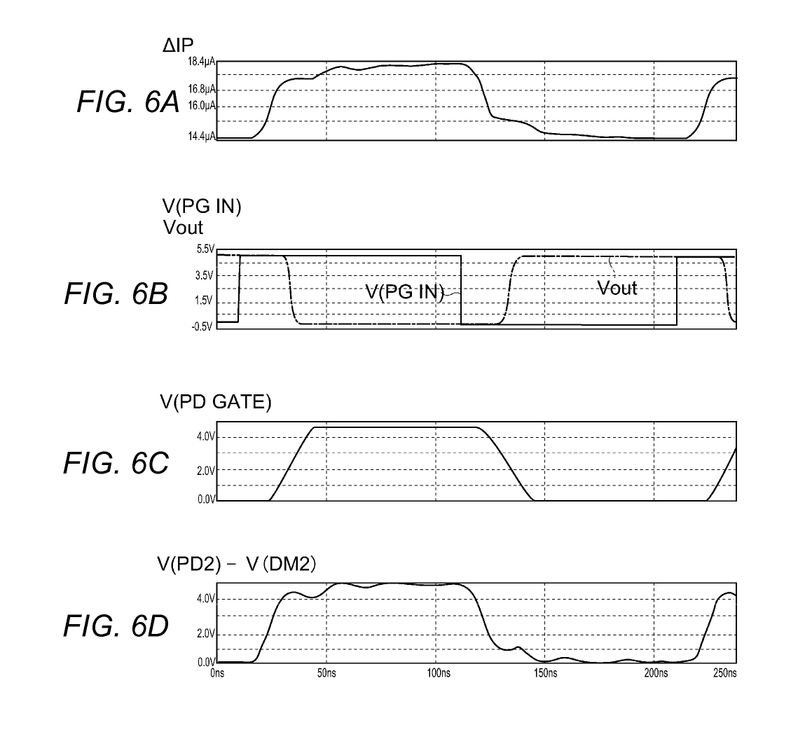

FIGS. 6A-D are a waveform diagrams corresponding to operation of the transimpedance amplifier according to the third exemplary embodiment. Each vertical axis denotes, respectively from FIG. 6A to 6D, ΔIP (change of the photocurrent), Vout (output voltage) & V (PG IN) (input signal voltage), the voltage of a node PD_GATE, and the difference between the voltage of a node PD2 and the voltage of a node DM2. The horizontal axis each of FIGS. 6A-D denotes time in nanoseconds (ns) with the corresponding axis values for each of FIG. 6A-C being provided on FIG. 6D. As can be seen, the pulse width distortion in the rise and fall of the output voltage Vout is reduced.

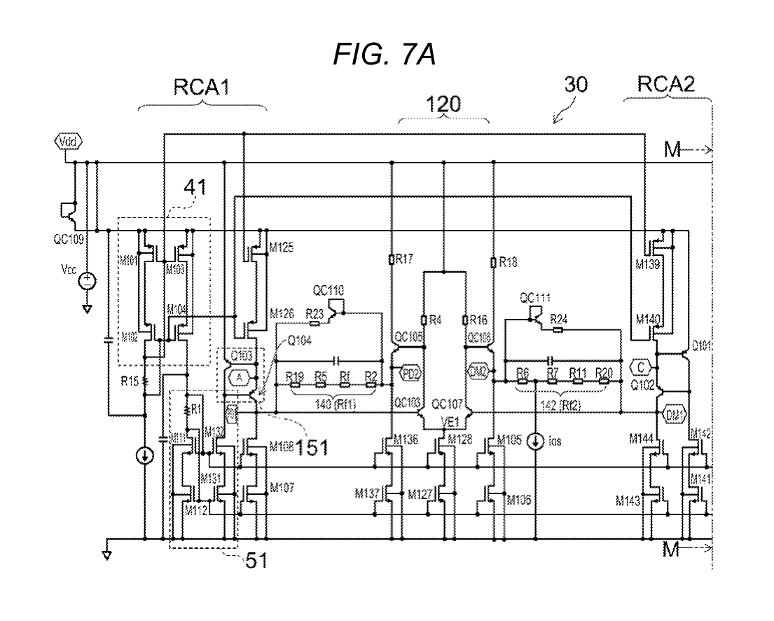

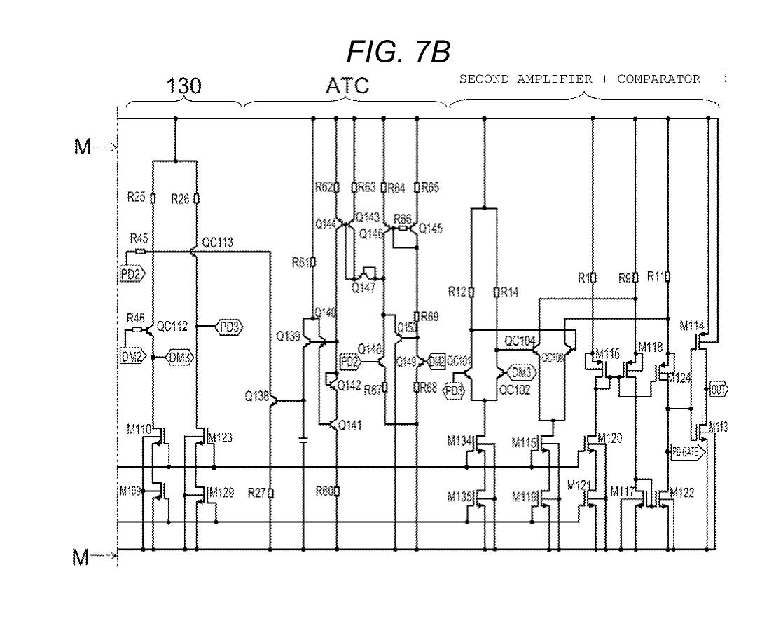

FIG. 7A and FIG. 7B are portions of a circuit diagram of a transimpedance amplifier according to a fourth exemplary embodiment. The circuit diagram is divided along line M-M. FIG. 7A depicts elements in the circuit diagram to the left of the line M-M and FIG. 7B depicts elements in the circuit diagram to the right of the line M-M. A resistor is set as a load of a differential amplifier 120. In addition, an emitter follower circuit is used to obtain the output of the differential amplifier 120. The ATC circuit including a peak hold circuit and a resistor R45 may be provided in the post-stage of a differential buffer amplifier 130. Furthermore, a second amplifier and a comparator may be provided in the post-stage of the ATC circuit.

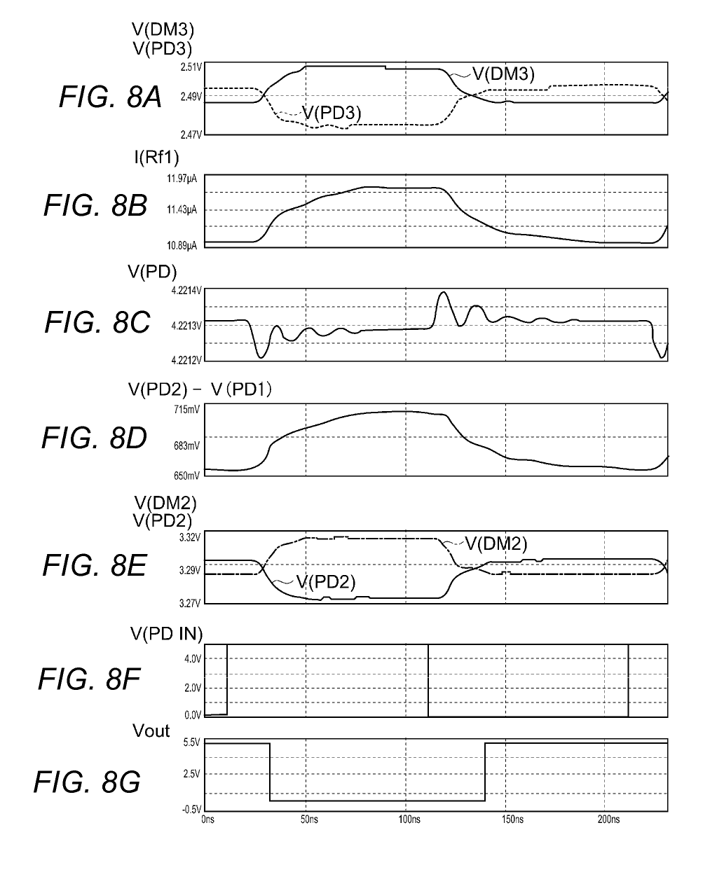

FIGS. 8A-G are waveform diagrams corresponding to operation of the transimpedance amplifier according to the fourth exemplary embodiment.

Each vertical axis respectively denotes the voltages of a node PD3 and DM3 (FIG. 8A), the current flowing through a feedback resistor Rf1 (FIG. 8B), the voltage of a node PD (FIG. 8C), the difference between the voltage of a node PD2 and the voltage of a node PD1 (FIG. 8D), the voltages of the node PD2 and a node DM2 (FIG. 8E), the voltage of a node PD_IN (FIG. 8F), and the output voltage Vout (FIG. 8G). The horizontal axis of each of FIGS. 8A-G correspond to each other and represent time in nanoseconds. The pulse width distortion in the rise and fall of the output voltage Vout is reduced. The peak hold circuit divides the voltage difference between the voltages V(PD2) of the node PD2 and V(DM2) of the node DM2 by the value of an emitter resistor (R67+R68) to convert the voltage difference to a current difference (the collector current of Q147). A negative feedback current is determined through the peak hold by using the current mirror ratio between resistors R60 and R27. A negative feedback ratio is determined by the product of the negative feedback current and the value of the resistor R45. When the negative feedback ratio is set to be in a range of 0.1 to 0.5, unintended activation caused by overdrive may be suppressed, and the pulse width distortion may be reduced.

According to the first to fourth exemplary embodiments, the photodiode 20 is biased by the regulated cascode circuit including the negative feedback loop. For this reason, the photodiode 20 is charged and discharged with high speed. In addition, the minimum operating power supply voltage may be reduced, and power consumption maybe decreased. Furthermore, the conversion efficiency may be substantially doubled by connecting the photodiode in a parallel manner. Such a transimpedance amplifier and a light reception circuit may be used in optical coupling devices, photo relays, optical coupling type insulation circuits, and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A transimpedance amplifier, comprising:
a first current source that includes a first cascode circuit with two transistors;
a second current source that includes a second cascode circuit with two transistors;
an output amplifier having a first input terminal at which an output of the first cascode circuit is input and a first output terminal at which an output voltage corresponding to a photocurrent is output;
a first feedback resistor connected between the first input terminal and the first output terminal; and
a bias circuit connected between the first current source and the second current source, the first current source being connected between the bias circuit and a ground terminal, the second current source being connected between a power supply terminal and the bias circuit, the input terminal of the output amplifier being connected to a first feedback node between the bias circuit and the first current source,
wherein a photocurrent supplied at a photocurrent terminal corresponds to a first current from the first current source subtracted from a sum of a second current from the second current source and a first feedback current from the first input terminal of the output amplifier.

2. The transimpedance amplifier according to claim 1, wherein the output amplifier is a differential amplifier that further includes a second input terminal and a second output terminal.

3. The transimpedance amplifier according to claim 2, further comprising:
a second feedback resistor connected to the second input terminal and the second output terminal of the output amplifier.

4. The transimpedance amplifier according to claim 3, further comprising:
a third current source that includes a third cascode circuit with two transistors;
a fourth current source that includes a fourth cascode circuit with two transistors;
a reference current terminal through which a reference current passes; and
a bipolar transistor between the third current source and the fourth current source having a base connected to the reference current terminal and a collector connected to the second input terminal of the output amplifier,
wherein the reference current corresponds to a current from the third current source subtracted from a sum of a fourth current from the fourth current source and a second feedback current from the second output terminal of the output amplifier.

5. The transimpedance amplifier according to claim 4, further comprising a comparator circuit connected to the first and second output terminals of the output amplifier.

6. The transimpedance amplifier according to claim 4, wherein
the third cascode circuit includes an N-channel MOS transistor, and
the fourth cascode circuit includes a P-channel MOS transistor.

7. The transimpedance amplifier according to claim 2, further comprising:
a third current source that includes a third cascode circuit with two transistors;
a fourth current source that includes a fourth cascode circuit with two transistors;
a reference current terminal through which a reference current passes; and
a bipolar transistor between the third current source and the fourth current source having a base connected to the reference current terminal and a collector connected to the second input terminal of the output amplifier,
wherein the reference current corresponds to a current from the third current source subtracted from a sum of a fourth current from the fourth current source and a second feedback current from the second output terminal of the output amplifier.

8. The transimpedance amplifier according to claim 2, wherein
the first cascode circuit includes an N-channel MOS transistor,
the second cascode circuit includes a P-channel MOS transistor, and
the bias circuit includes a PNP bipolar transistor.

9. The transimpedance amplifier according to claim 1, wherein
the first cascode circuit includes an N-channel MOS transistor,
the second cascode circuit includes a P-channel MOS transistor, and
the bias circuit includes a PNP bipolar transistor.

10. The transimpedance amplifier according to claim 1, further comprising:
a photocurrent clamp circuit between the first current source and the ground terminal.

11. The transimpedance amplifier according to claim 10, wherein the photocurrent clamp circuit is an emitter follower circuit formed by an NPN bipolar transistor.

12. A transimpedance amplifier, comprising:
a first current source that includes a first cascode circuit with two transistors, the first current source connected to a ground terminal;
a differential amplifier that includes a first transistor having a first control electrode that is connected to a photocurrent terminal and a second transistor having a second control electrode that is connected to a reference current terminal;
a differential buffer amplifier connected to the differential amplifier;
a first feedback resistor connected to the photocurrent terminal and a first output terminal of the differential buffer amplifier;
a second feedback resistor connected to the reference current terminal and a second output terminal of the differential buffer amplifier; and
a bias circuit connected between a power supply terminal and the first current source and configured to control a photocurrent supplied at a photocurrent terminal by negatively feeding back a voltage of the photocurrent terminal to the photocurrent terminal.

13. The transimpedance amplifier according to claim 12, further comprising:
a photocurrent clamp circuit connected in parallel to the first feedback resistor.

14. The transimpedance amplifier according to claim 12, further comprising a comparator circuit connected to the first and second output terminals of the output amplifier.

15. A transimpedance amplifier, comprising:
a photocurrent terminal through which a photocurrent passes;
a reference current terminal through which a reference current passes;
a first current source that includes a first cascode circuit with two transistors;
a second current source that includes a second cascode circuit with two transistors;
a bias circuit connected between the first current source and the second current source, and that is configured to control a photocurrent supplied at a photocurrent terminal by negatively feeding back a voltage of the photocurrent terminal to the photocurrent terminal;
a differential amplifier that includes a first transistor including a first control electrode at which an output of the bias circuit is input and a second transistor including a second control electrode at which a reference signal corresponding to a reference current that is supplied at a reference terminal is input;
a first feedback resistor connected to the first control electrode and a first output of the differential amplifier; and
a second feedback resistor connected to the second control electrode and a second output of the differential amplifier.

16. The transimpedance amplifier according to claim 15, further comprising:
a photocurrent clamp circuit connected in parallel to the first feedback resistor.

17. The transimpedance amplifier according to claim 15, further comprising a comparator circuit connected to the first and second output terminals of the output amplifier.

18. A light reception circuit including the transimpedance amplifier according to claim 1, and further comprising:
a photodiode between the photocurrent terminal and the ground terminal.

19. A light reception circuit including the transimpedance amplifier according to claim 12, and further comprising:
a first photodiode between the photocurrent terminal and the ground terminal; and
a second photodiode between the reference current terminal and the ground terminal, wherein the second photodiode is shielded from exposure to light.

20. A light reception circuit including the transimpedance amplifier according to claim 15, and further comprising:
a first photodiode between the photocurrent terminal and the ground terminal; and
a second photodiode between the reference current terminal and the ground terminal, wherein the second photodiode is shielded from exposure to light.
